(19) United States
(12) Patent Application Publication
(10) Pub. No.: US 2025/0234726 A1
(43) Pub. Date: Jul. 17, 2025

(54) DISPLAY SUBSTRATE AND DISPLAY DEVICE

(71) Applicants: CHENGDU BOE OPTOELECTRONICS TECHNOLOGY CO., LTD., Chengdu (CN); BOE TECHNOLOGY GROUP CO., LTD., Beijing (CN)

(72) Inventors: Xiangnan Pan, Beijing (CN); Xiaomin Yuan, Beijing (CN); Qing He, Beijing (CN); Qingqing Yan, Beijing (CN); Chi Yu, Beijing (CN); Ge Wang, Beijing (CN); Zhiliang Jiang, Beijing (CN); Tiaomei Zhang, Beijing (CN); Ziyang Yu, Beijing (CN); Fang Fang, Beijing (CN); Ming Hu, Beijing (CN); Min Chen, Beijing (CN)

(21) Appl. No.: 18/702,783

(22) PCT Filed: Mar. 27, 2023
(86) PCT No.: PCT/CN2023/083965

§ 371 Date: Apr. 18, 2024

(51) Int. Cl. H10K 59/131; H10K 59/122; H10K 59/123; H10K 59/35; H10K 59/40; H10K 59/80

(52) U.S. Cl. CPC H10K 59/131; H10K 59/122; H10K 59/123; H10K 59/353; H10K 59/8792; H10K 59/40

(57) ABSTRACT

Provided are a display substrate and a display device. The display substrate includes: a base substrate; a driving circuit layer; a pixel defining layer defining pixel openings for pixels; at least part of a light emitting unit layer is provided in the pixel openings, the light emitting unit layer includes an anode layer near the driving circuit layer, the anode layer includes a first anode region partially located in the pixel openings and a second anode region located outside the pixel openings, and the first anode region and the second anode region of a same pixel are electrically connected; a black matrix layer defining black matrix openings; and a color filter layer. Overlapping regions are formed by orthographic projections of the driving circuit layer and the first anode region on the base substrate, and wires of the driving circuit layer in at least part of the overlapping regions are axisymmetric.

### CROSS REFERENCE TO RELATED APPLICATION(S)

This application is a Section 371 National Stage Application of International Application No. PCT/CN2023/083965, filed on Mar. 27, 2023, the whole disclosure of which is incorporated herein by reference in its entirety.

### TECHNICAL FIELD

The present disclosure relates to the field of display technology, and in particular, to a display substrate and a display device.

### BACKGROUND

With a development of the display technology, a display effect of a display has become particularly important. In order to meet increasingly higher requirements for the display effect, increase an exit light gain and further improve an integration, a COE (Colorfilter On Encapsulation) structure instead of a polarizer solution is used in an OLED product, in which a color filter CF is prepared above an anode pixel structure, so that a black screen on display effect of a product may be achieved, while the exit light gain of the product may be improved.

### SUMMARY

The embodiments of the present disclosure provide a display substrate and a display device.

In an aspect, a display substrate is provided, including but not being limited to: a base substrate; a driving circuit layer provided on a side of the base substrate; a pixel defining layer located on a side of the driving circuit layer away from the base substrate, the pixel defining layer defines pixel openings for a plurality of pixels, and the pixel openings are arranged in an array; a light emitting unit layer, at least part of the light emitting unit layer is provided in the pixel openings, the light emitting unit layer includes an anode layer close to the driving circuit layer, the anode layer includes a first anode region partially located in the pixel openings and a second anode region located outside the pixel openings, and the first anode region and the second anode region of a same pixel are electrically connected; a black matrix layer provided on a side of the pixel defining layer away from the base substrate, the black matrix layer defines a plurality of black matrix openings, and an orthographic projection of the black matrix openings on the base substrate overlaps with an orthographic projection of the pixel openings on the base substrate; and a color filter layer provided at least partially in the black matrix openings, an orthographic projection of the driving circuit layer on the base substrate and an orthographic projection of the first anode region on the base substrate form a plurality of overlapping regions, and wires of the driving circuit layer in at least part of the overlapping regions exhibit an axisymmetric pattern.

In some exemplary embodiments of the present disclosure, the plurality of overlapping regions include a plurality of first overlapping regions and a plurality of second overlapping regions, and the first overlapping region and the second overlapping region are located in the pixel openings for different pixels; and the driving circuit layer includes a first wire, the first wire includes a power signal wire and a data signal wire, the power signal wire and the data signal wire in at least part of the first overlapping regions respectively exhibit an axisymmetric pattern; or the first wire includes a power signal wire, and the power signal wire in at least part of the first overlapping regions exhibits an axisymmetric pattern; or the first wire includes a data signal wire, and the data signal wire in at least part of the first overlapping regions exhibits an axisymmetric pattern.

In some exemplary embodiments of the present disclosure, the driving circuit layer includes a second wire, and the second wire and the power signal wire in the second overlapping region respectively exhibit an axisymmetric pattern.

In some exemplary embodiments of the present disclosure, in the second overlapping region, a total area of the power signal wire is greater than or equal to an area of the first anode region, or a total area of the second wire and the power signal wire is greater than or equal to the area of the first anode region.

In some exemplary embodiments of the present disclosure, when the power signal wire and the data signal wire in at least part of the first overlapping regions respectively exhibit an axisymmetric pattern, symmetry axes of the axisymmetric patterns coincide with each other.

In some exemplary embodiments of the present disclosure, the second wire includes a first shape compensation portion located in the second overlapping region, at least part of an outer contour of the first shape compensation portion has the same shape as at least part of an outer contour of the first anode region, and an orthographic projection of the first shape compensation portion on the base substrate overlaps at least partially with an orthographic projection of the power signal wire on the base substrate.

In some exemplary embodiments of the present disclosure, the power signal wire includes a second shape compensation portion located in the second overlapping region, and at least part of an outer contour of the second shape compensation portion has the same shape as at least part of an outer contour of the first anode region.

In some exemplary embodiments of the present disclosure, the anode layer is electrically connected to the wire of the driving circuit layer through an anode via hole in the second anode region.

In some exemplary embodiments of the present disclosure, the pixels include first sub-pixels, second sub-pixels, and third sub-pixels; the first sub-pixels and the second sub-pixels are respectively located in different first overlapping regions, and the third sub-pixels are located in the second overlapping regions; the first sub-pixels and the second sub-pixels are alternately arranged in a first direction and a second direction, and the first direction and the second direction form a plane parallel to an upper surface of the base substrate; and the third sub-pixels are arranged in an array in the first direction and the second direction, and the third sub-pixels are located between adjacent first sub-pixels and between adjacent second sub-pixels.

In some exemplary embodiments of the present disclosure, the orthographic projection of the pixel opening on the base substrate is located within the orthographic projection of the first anode region on the base substrate.

In some exemplary embodiments of the present disclosure, the orthographic projection of the pixel opening on the base substrate is located within the orthographic projection of the black matrix opening on the base substrate.

In some exemplary embodiments of the present disclosure, the driving circuit layer defines a plurality of first hollow regions located between adjacent first overlapping regions and between adjacent second overlapping regions.

In some exemplary embodiments of the present disclosure, the first hollow region is located between adjacent data signal wires, the data signal wire includes a bending portion and a body portion, the body portion is located in the first overlapping region, and the bending portion of the data signal wire is bent toward a direction away from the first hollow region with respect to the body portion.

In some exemplary embodiments of the present disclosure, adjacent bending portions of the data signal wires located on a periphery of the first hollow region exhibit an axisymmetric pattern.

In some exemplary embodiments of the present disclosure, the pixel defining layer defines a plurality of second hollow regions, and an orthographic projection of the second hollow region on the base substrate is located within an orthographic projection of the first hollow region on the base substrate.

In some exemplary embodiments of the present disclosure, the black matrix layer defines a plurality of third hollow regions, and an orthographic projection of the third hollow region on the base substrate is located within the orthographic projection of the first hollow region on the base substrate.

In some exemplary embodiments of the present disclosure, the first hollow region, the second hollow region, and the third hollow region are located between a plurality of pixels.

In some exemplary embodiments of the present disclosure, the second hollow region has the same shape as the third hollow region.

In some exemplary embodiments of the present disclosure, the display substrate further includes a touch layer, the touch layer includes a touch sensing region provided at a diagonal intersection of four adjacent second hollow regions of the display substrate, and the touch sensing region is located between four adjacent sub-pixels.

In some exemplary embodiments of the present disclosure, the pixel opening, the first anode region, and the black matrix opening have the same shape including a circle.

In some exemplary embodiments of the present disclosure, the pixel opening for at least one of the first sub-pixel, the second sub-pixel or the third sub-pixel has a different size from the pixel openings for other pixels.

In some exemplary embodiments of the present disclosure, the black matrix layer includes at least one of a black metal, a black organic material, or a black inorganic material.

In another aspect of the present disclosure, a display device is provided, including the display substrate as described above.

### BRIEF DESCRIPTION OF THE DRAWINGS

With the following descriptions of the present disclosure with reference to the drawings, other objectives and advantages of the present disclosure may be obvious, and the present disclosure may be understood comprehensively, in which:

FIG. 1 shows a schematic plan view of a display substrate according to the embodiments of the present disclosure;

FIG. 2 shows a partial plan view of a display substrate according to some exemplary embodiments of the present disclosure;

FIG. 3 shows a schematic cross-sectional view of the display substrate according to some exemplary embodiments of the present disclosure taken along line A-A′ in FIG. 2;

FIG. 4 shows a partial plan view of a display substrate including a driving circuit and other film layers according to some exemplary embodiments of the present disclosure;

FIG. 5 shows a partial plan view of a display substrate including a light emitting unit layer and other film layers according to some exemplary embodiments of the present disclosure;

FIG. 6 shows a partial plan view of a display substrate including a black matrix layer and other film layers according to some exemplary embodiments of the present disclosure;

FIG. 7 shows a partial plan view of a display substrate according to some other exemplary embodiments of the present disclosure;

FIG. 8 shows a partial plan view of a display substrate including a driving circuit and other film layers according to some other exemplary embodiments of the present disclosure;

FIG. 9 shows a partial plan view of a display substrate including a light emitting unit layer and other film layers according to some other exemplary embodiments of the present disclosure;

FIG. 10 shows a partial plan view of a display substrate including a black matrix layer and other film layers according to some other exemplary embodiments of the present disclosure;

FIG. 11 shows a partial plan view of a hollow region of a display substrate according to some other exemplary embodiments of the present disclosure;

FIG. 12 shows a partial plan view of a light emitting unit of a display substrate according to some other exemplary embodiments of the present disclosure.

It should be noted that for the sake of clarity, in the drawings used to describe the embodiments of the present disclosure, sizes of layers, structures or regions may be enlarged or reduced, that is, those drawings are not drawn according to actual scale.

### DETAILED DESCRIPTION OF EMBODIMENTS

Technical solutions of the present disclosure will be further described in detail below through the embodiments with reference to the drawings. In the specification, the same or similar reference numerals represent the same or similar components. The following descriptions of the embodiments of the present disclosure with reference to the drawings are intended to explain a general inventive concept of the present disclosure, and should not be understood as a limitation to the present disclosure.

In addition, in the following detailed descriptions, for convenience of explanation, many specific details are set forth to provide a comprehensive understanding of the embodiments of the present disclosure. However, it is obvious that one or more embodiments may also be implemented without these specific details.

It should be noted that although the terms “first”, “second”, and so on may be used here to describe various components, members, elements, regions, layers and/or portions, these components, members, elements, regions, layers and/or portions should not be limited by these terms. Rather, these terms are used to distinguish one component, member, element, region, layer and/or portion from another. Thus, for example, a first component, a first member, a first element, a first region, a first layer and/or a first portion discussed below may be referred to as a second component, a second member, a second element, a second region, a second layer and/or a second portion without departing from teachings of the present disclosure.

For ease of description, spatial relationship terms, such as “upper”, “lower”, “left”, “right”, etc., may be used here to describe a relationship between an element or feature and another element or feature as shown in the drawings. It should be understood that the spatial relationship terms are intended to cover other different orientations of a device in use or operation in addition to the orientation described in the drawings. For example, if a device in the drawing is turned upside down, an element or feature described as “below” or “under” another element or feature will be oriented “above” or “on” the another element or feature.

Herein, the terms “substantially”, “about”, “approximately”, “roughly” and other similar terms are used as terms of approximation rather than terms of degree, and they are intended to explain an inherent deviation of a measured or calculated value that will be recognized by those ordinary skilled in the art. Taking into account a process fluctuation, a measurement problem, an error related to a measurement of a specific quantity (that is, a limitation of a measurement system) and other factors, the term “about” or “approximately” used here includes a stated value and means that a specific value determined by those ordinary skilled in the art is within an acceptable range of deviation. For example, “about” may mean being within one or more standard deviations, or within ±30%, ±20%, ±10% or ±5% of the stated value.

It should be noted that the expressions “same layer” herein refer to a layer structure that is formed by firstly forming, using a same film forming process, a film layer used to form a specific pattern, and then patterning, using one-time patterning process, the film layer with a same mask. Depending on different specific patterns, the one-time patterning process may include a plurality of exposure, development or etching processes, and the specific pattern in the formed layer structure may be continuous or discontinuous. That is, a plurality of elements, components, structures and/or portions located in the “same layer” are made of the same material and formed by the same patterning process. Generally, a plurality of elements, components, structures and/or portions located in the “same layer” have substantially the same thickness.

Those skilled in the art should understand that, unless otherwise specified, the expressions “continuously extending”, “integral structure”, “overall structure” or similar expressions herein mean that a plurality of elements, components, structures and/or portions are located in the same layer and generally formed by the same patterning process during the manufacturing process, and these elements, components, structures and/or portions are not separated or broken, but are formed as a continuously extending structure.

Herein, directional expressions “first direction” and “second direction” are used to describe different directions along a pixel region, e.g., a longitudinal direction and a lateral direction of the pixel region. It should be understood that such expressions are just exemplary descriptions and are not limitations to the present disclosure.

In the related art, in order to increase an exit light gain and further improve an integration, a COE structure may be used instead of a traditional polarizer solution, and a color filter CF may be prepared above an anode pixel structure to achieve a black screen on display effect of a product and also improve the exit light gain of the product. However, due to a gradual increase in a pixel density of existing products, for example, a TFT circuit layout space in QHD products is continuously compressed, and a circuit wire and an adapter hole below an anode may lead to a decrease in a flatness of the upper anode. When an external point light source illuminates a mobile phone screen, a diffraction may occur to form a diffraction ring and a color separation. In a case of a poor flatness, the diffraction ring may be greatly enlarged to cause a ring distortion, which may further worsen the color separation and significantly reduce the display effect.

To address the aforementioned problems, the embodiments of the present disclosures provide a display substrate, including but not limited to: a base substrate; a driving circuit layer provided on a side of the base substrate; a pixel defining layer located on a side of the driving circuit layer away from the base substrate, the pixel defining layer defines pixel openings for a plurality of pixels, and the pixel openings are arranged in an array; a light emitting unit layer, at least part of the light emitting unit layer is provided in the pixel openings, the light emitting unit layer includes an anode layer close to the driving circuit layer, the anode layer includes a first anode region partially located in the pixel openings and a second anode region located outside the pixel openings, and the first anode region and the second anode region of a same pixel are electrically connected; a black matrix layer provided on a side of the pixel defining layer away from the base substrate, the black matrix layer defines a plurality of black matrix openings, and an orthographic projection of the black matrix openings on the base substrate overlaps with an orthographic projection of the pixel openings on the base substrate; and a color filter layer provided at least partially in the black matrix openings; an orthographic projection of the driving circuit layer on the base substrate and an orthographic projection of the first anode region on the base substrate form a plurality of overlapping regions, and wires of the driving circuit layer in at least part of the overlapping regions exhibit an axisymmetric pattern.

According to the embodiments of the present disclosure, with an arrangement that the orthographic projection of the driving circuit layer on the base substrate and the orthographic projection of the first anode region in the pixel openings on the base substrate form overlapping regions, and the wires of the driving circuit in the overlapping regions exhibit an axisymmetric pattern, the first anode region located above the wire of the driving circuit may have a good flatness, so that the display effect of the COE product may be effectively improved.

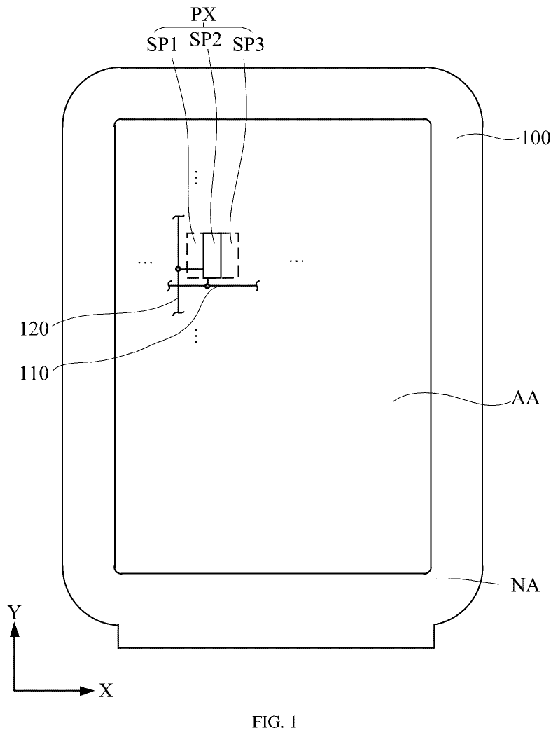

The display substrate of the embodiments of the present disclosure will be described in detail below with reference to FIG. 1 to FIG. 11.

FIG. 1 shows a schematic plan view of a display substrate according to the embodiments of the present disclosure. Referring to FIG. 1, the display substrate according to the embodiments of the present disclosure may include a base substrate 100 and a pixel unit PX provided on the base substrate 100.

The display substrate may include a display region AA and a non-display region NA. The display region AA may be a region in which pixel units PX for displaying images are provided. Each pixel unit PX will be described later. The non-display region NA may be a region in which no pixel unit PX is provided, that is, a region in which no image is displayed. The non-display region NA corresponds to a bezel in a final display device, and a width of the bezel may be determined according to a width of the non-display region NA.

The display region AA may have various shapes. For example, the display region AA may be provided in various shapes such as a closed polygon including straight sides (e.g., a rectangle), a circle, an ellipse, etc. that includes a curved side, and a semicircle, a semi-ellipse, etc. that includes a straight side and a curved side. In the embodiments of the present disclosure, the display region AA is provided as a region having a quadrangular shape including straight sides. It should be understood that this is just an exemplary embodiment of the present disclosure, rather than a limitation to the present disclosure.

The non-display region NA may be arranged on at least one side of the display region AA. In the embodiments of the present disclosure, the non-display region NA may surround a periphery of the display region AA. In the embodiments of the present disclosure, the non-display region NA may include a transverse portion extending in a first direction X and a longitudinal portion extending in a second direction Y.

The pixel unit PX is arranged in the display region AA. The pixel unit PX is a minimum unit for displaying an image, and a plurality of pixel units may be provided. For example, the pixel unit PX may include light emitting device(s) emitting white light and/or color light.

A plurality of pixel units PX may be arranged in a matrix form along rows extending in the first direction X and columns extending in the second direction Y. However, the embodiments of the present disclosure do not specifically limit an arrangement form of the pixel units PX, and the pixel units PX may be arranged in various forms. For example, the pixel units PX may be arranged such that a direction inclined with respect to the first direction X and the second direction Y is a column direction, and a direction intersecting with the column direction is a row direction.

That is, a plurality of pixel units PX are arranged in an array in the first direction X and the second direction Y, so as to form a plurality of rows of pixel units and a plurality of columns of pixel units.

A pixel unit PX may include a plurality of sub-pixels. For example, a pixel unit PX may include three sub-pixels, namely a first sub-pixel SP1, a second sub-pixel SP2, and a third sub-pixel SP3. For example, the first sub-pixel SP1 may be a red sub-pixel, the second sub-pixel SP2 may be a green sub-pixel, and the third sub-pixel SP3 may be a blue sub-pixel.

It should be noted that in the embodiments of the present disclosure, the number of sub-pixels included in a pixel unit is not particularly restricted, and is not limited to the above-mentioned three.

For example, in the exemplary embodiments shown in FIG. 1, a scanning control signal line 110 and a data line 120 are schematically shown. That is, the display substrate may further include a plurality of scanning control signal lines 110 and a plurality of data lines 120 provided on the base substrate. The plurality of scanning control signal lines 110 respectively provide scanning control signals to a plurality of rows of pixel units, and the plurality of data lines 120 respectively provide data signals to a plurality of columns of pixel units. The scanning control signal line 110 extends in the first direction X, and the plurality of scanning control signal lines 110 are spaced apart in the second direction Y. The data line 120 extends in the second direction Y, and the plurality of data lines 120 are spaced apart in the first direction X.

For example, the scanning control signal line 110 may be a representative of a horizontal wire, and the data line 120 may be a representative of a vertical wire. It should be understood that the horizontal wire may further include other types of wires or other wires used to provide other signals, and the vertical wire may further include other types of wires or other wires used to provide other signals.

Exemplarily, the data line 120 may include, for example, a power signal wire (VDD) or a data signal wire (Data).

Each sub-pixel may include a light emitting element and a pixel driving circuit for driving the light emitting element. For example, in an OLED display substrate or display panel, the light emitting element of the sub-pixel may include an anode, a luminescent material layer and a cathode arranged in stack. The anodes of the light emitting elements of the sub-pixels are spaced apart, and arranged in a matrix form along rows extending in the first direction X and columns extending in the first direction Y.

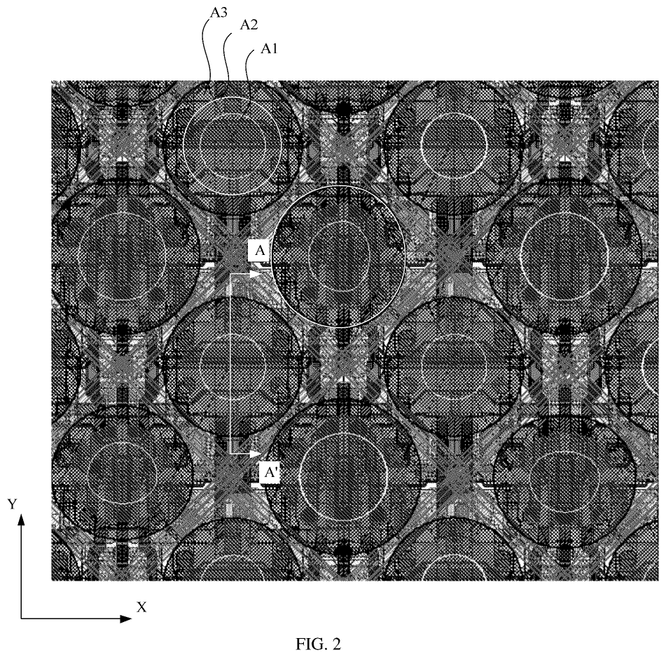

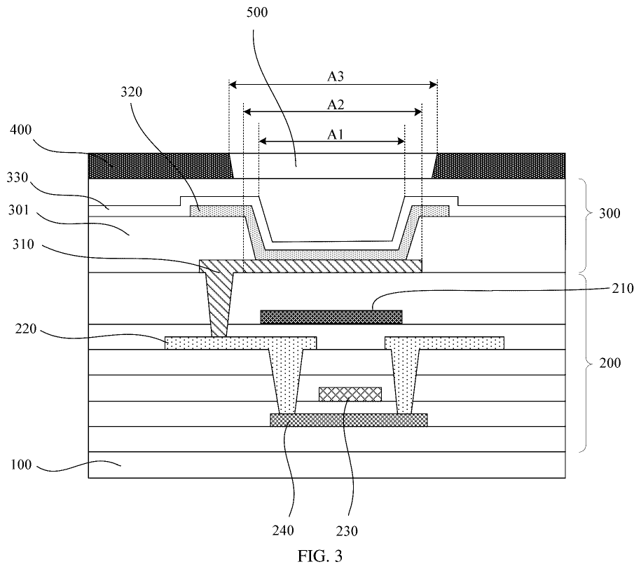

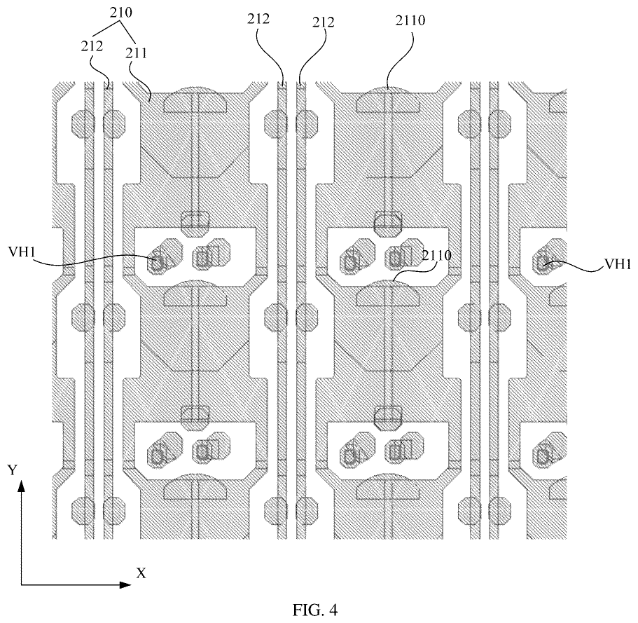

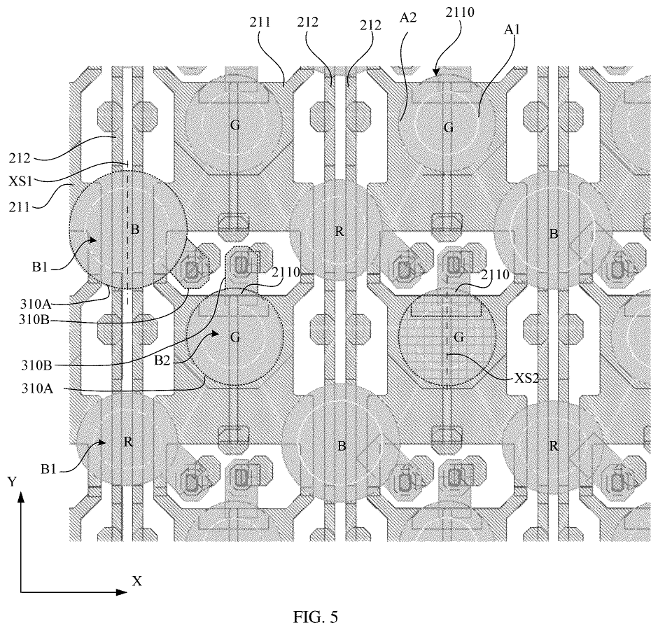

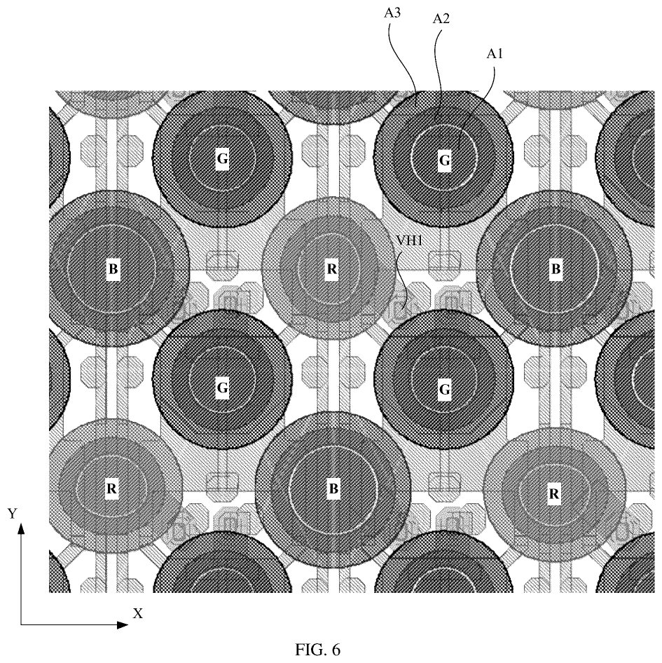

FIG. 2 shows a partial plan view of a display substrate according to some exemplary embodiments of the present disclosure. FIG. 3 shows a schematic cross-sectional view of the display substrate according to some exemplary embodiments of the present disclosure taken along line A-A′ in FIG. 2. FIG. 4 shows a partial plan view of a display substrate including a driving circuit and other film layers according to some exemplary embodiments of the present disclosure. FIG. 5 shows a partial plan view of a display substrate including a light emitting unit layer and other film layers according to some exemplary embodiments of the present disclosure. FIG. 6 shows a partial plan view of a display substrate including a black matrix layer and other film layers according to some exemplary embodiments of the present disclosure.

Examples of the display substrate in some exemplary embodiments of the present disclosure will be described below with reference to FIG. 2 to FIG. 6.

In some exemplary embodiments of the present disclosure, the display substrate includes a base substrate 100, a driving circuit layer 200, a light emitting unit layer 300, a pixel defining layer 301, a black matrix layer 400, and a color filter layer 500.

As shown in FIG. 3, the driving circuit layer 200 is provided on the base substrate 100, and the driving circuit layer 200 includes a plurality of layers of conductive materials and a plurality of layers of insulation materials.

Exemplarily, a material of the base substrate 100 may be, for example, polyethylene terephthalate (PET), polyimide (PI), cyclo olefin polymer (COP), or a glass substrate, etc.

A structure of a driving circuit in the driving circuit layer 200 may be, for example, a driving circuit structure having various functions, which may be selected and set according to actual needs. For example, the driving circuit may include at least two transistors and at least one capacitor. For example, the pixel circuit may have a structure such as “2T1C”, “6T1C”, “7T1C”, “6T2C”, or “7T2C”, etc., where “T” represents a thin-film transistor, the number before “T” represents the number of thin-film transistors, “C” represents a storage capacitor, and the number before “C” represents the number of storage capacitors.

In the embodiments of the present disclosure, the pixel driving circuit may be an LTPO circuit, which is prepared using a low temperature poly silicon (LTPS) technology and oxide (IGZO). The low temperature poly silicon (LTPS) technology may, for example, form an active layer using a poly silicon deposition, and the LTPS has a high electron mobility, a fast response speed, and advantages such as high brightness, high resolution, and low power consumption. An oxide thin-film transistor (Oxide TFT) may use, for example, an oxide semiconductor such as indium gallium zinc oxide (IGZO), as an active layer of TFT. The oxide semiconductor has a high electron mobility and good turn-off characteristics. Compared with LTPS, the oxide semiconductor has a simple manufacture process and a high compatibility with an amorphous silicon manufacture process. Certainly, the oxide thin-film transistor may also be other metal oxide semiconductors, such as indium zinc tin oxide (IZTO) or indium gallium zinc tin oxide (IGZTO), etc. The use of oxide thin-film transistor may effectively reduce a size of the transistor and prevent a leakage current, so that the pixel circuit may be applied to low-frequency driving, while a resolution of the display substrate may be improved.

The conductive material in the driving circuit layer 200 may include, for example, a metal oxide such as indium tin oxide, etc., or a metal such as silver Ag, aluminum Al, etc., or a semiconductor material. The insulation material in the driving circuit layer may include, for example, acrylic resin, epoxy resin, imide resin, or ester resin.

The insulation material in the driving circuit layer 200 separates the conductive materials located in different layers of the driving circuit layer, and via holes are provided between the insulation material layers to electrically connect the conductive materials of different layers, thereby forming a required structure of the driving circuit.

In the embodiments of the present disclosure, the light emitting unit layer 300 and the pixel defining layer 301 are provided on a side of the driving circuit layer away from the base substrate. As shown in FIG. 3, the pixel defining layer 301 is located on a side of the driving circuit layer 200 away from the base substrate, and the pixel defining layer defines a plurality of pixel openings A1. As shown in FIG. 5 and FIG. 6, the pixel openings are arranged in an array, for example, in the first direction X and the second direction Y.

For example, sizes of pixel openings for different pixels may be designed according to an actual display effect, so that different display effects may be achieved for different colors. Exemplarily, in the pixel openings defined by the pixel defining layer in the display substrate, the pixel openings for different colors have different sizes. For example, the pixels include a red pixel R, a blue pixel B and a green pixel G, and the pixel openings for the red pixel R, the blue pixel B and the green pixel G may have different sizes. For another example, the pixel opening for the blue pixel and the pixel opening for the green pixel have the same size, and the pixel opening for the red pixel has a different size from the pixel opening for the blue pixel and the pixel opening for the green pixel.

Exemplarily, shapes of the pixel openings for pixels of different colors may be designed according to actual needs. At least part of the shapes of the pixel openings is a regular shape, such as a circle, a rectangle, a regular polygon, etc. The shapes of the pixel openings may also include some irregular shapes.

For example, as shown in FIG. 6, the blue pixel B and the green pixel G are provided as regular pixel openings, both of which are circular pixel openings, while the red pixel R is provided as an irregular pixel opening to meet different pixel layout requirements, so as to improve a space utilization of a display panel and increase a display density while ensuring the display effect.

In some embodiments of the present disclosure, as shown in FIG. 3, the light emitting unit layer 300 forms a light emitting element. At least part of the light emitting unit layer 300 is provided within the pixel opening A1. The light emitting unit layer 300 includes an anode layer 310 close to the driving circuit layer, a luminescent material layer 320 on a side of the anode layer 310 away from the base substrate 100, and a cathode layer 330 on a side of the luminescent material layer 320 away from the base substrate 100.

As shown in a dashed box in FIG. 5, the anode layer 310 includes a first anode region 310A (circular dashed box) located partially in the pixel opening and a second anode region 310B (irregular-shaped dashed box) located outside the pixel opening. The first anode region 310A and the second anode region 310B of the same pixel are electrically connected, and the first anode region 310A and the second anode region 310B of the anode layer 310 are connected as a whole, so as to transmit an electrical signal to the luminescent material layer 320 and cause the luminescent material layer 320 to emit light. The first anode region 310A is located partially in the pixel opening. For example, both the first anode region 310A and the pixel opening A1 are circles, and a center of the first anode region 310A coincides with a center of the pixel opening A1. As shown in FIG. 3, an orthographic projection of the first anode region 310A on the base substrate 100 is A2, and an area of the orthographic projection A2 of the first anode region 310A on the base substrate is greater than an area of an orthographic projection of the pixel opening A1 on the base substrate.

Exemplarily, the first anode region 310A is electrically connected to the second anode region 310B, and the second anode region 310B extends away from the first anode region 310A in a plane direction parallel to the base substrate. The anode layer 310 is electrically connected to other wires of the driving circuit layer 200 through an anode via hole VH1.

In some embodiments, an orthographic projection of the anode via hole VH1 on the base substrate overlaps at most partially, for example, overlaps only partially or does not overlap, with an orthographic projection of the color filter layer 500 to be described below on the base substrate.

According to the embodiments of the present disclosures, a flatness of the anode region of each pixel has a significant impact on the display effect of the display substrate, and the via hole in the anode region may has a significant impact on the flatness of the film layer on a side of the anode region away from the base substrate. In the present disclosure, the anode layer below each pixel is provided as the first anode region and the second anode region extending away from the first anode region in the plane direction parallel to the base substrate, the second anode region is located outside the pixel opening, and the anode layer is electrically connected to the wire in the driving circuit layer through the anode via hole in the second anode region, so that the anode via hole avoids a position of the pixel opening for each pixel, then the flatness of other film layers in the pixel opening may be ensured, and the display effect of the display substrate may be improved.

In some exemplary embodiments of the present disclosure, the display substrate further includes a black matrix layer 400 on a side of the pixel defining layer 300 away from the base substrate 100. The black matrix layer 400 defines a plurality of black matrix openings A3, and an orthographic projection of the black matrix opening A3 on the base substrate 100 overlaps with the orthographic projection of the pixel opening A1 on the base substrate.

Exemplarily, as shown in FIG. 6, the orthographic projection of the black matrix opening A3 on the base substrate is a circle, and the orthographic projection of the pixel opening A1 on the base substrate is also a circle. These two circles are concentric, and the circle of the orthographic projection of the pixel opening A1 on the base substrate is located within the circle of the orthographic projection of the black matrix opening A3 on the base substrate.

In other optional embodiments, the orthographic projection of the black matrix opening A3 on the base substrate may be of other shapes, and the orthographic projection of the pixel opening A1 on the base substrate may be of the same shape, or other suitable shapes.

In some exemplary embodiments of the present disclosure, the display substrate further includes a color filter layer 500, and at least part of the color filter layer 500 is provided within the black matrix opening A3. For example, the color filter layer 500 and the black matrix layer 400 are located in the same layer, and the color filter layer 500 has the same thickness as the black matrix layer 400. The color filter layer 500 is filled within the black matrix opening A3, and a surface of the color filter layer away from the base substrate is located on a same plane or almost on a same plane as a surface of the black matrix layer away from the base substrate. In other optional embodiments, the orthographic projection of the black matrix opening on the base substrate is located within the orthographic projection of the color filter layer on the base substrate. The thickness of the color filter layer is greater than the thickness of the black matrix layer, and a size of the color filter layer is greater than a size of the black matrix opening. A part of the color filter layer is filled within the black matrix opening, and a remaining part of the color filter layer covers the black matrix layer on a side of the black matrix layer away from the base substrate. The surface of the color filter layer away from the base substrate is substantially a flat surface. According to the embodiments of the present disclosure, by providing the color filter layer within the black matrix opening, a diffraction of incident light may be reduced, then a dark state color separation may be improved.

In some embodiments of the present disclosure, the black matrix layer contains at least one selected from a black metal, a black organic material, or a black inorganic material.

In some embodiments of the present disclosure, an orthographic projection of the driving circuit layer 200 on the base substrate and an orthographic projection of the first anode region 310A on the base substrate form an overlapping region, and wires of the driving circuit layer in the overlapping region exhibit an axisymmetric pattern.

Exemplarily, the driving circuit layer 200 includes a plurality of wires, for example, a power signal wire, a data signal wire, etc. The wires of the driving circuit layer 200 in the overlapping region exhibit an axisymmetric pattern. For example, the wires in the overlapping region has a symmetry axis, and the wires on two sides of the symmetry axis are symmetrical and have the same function. For example, an axial direction of the symmetry axis is parallel to a length direction of the power signal wire or a length direction of the data signal wire.

In the embodiments of the present disclosure, there may be a plurality of overlapping regions. As shown in FIG. 5, the plurality of overlapping regions include a plurality of first overlapping regions B1 and a plurality of second overlapping regions B2. The first overlapping region B1 and the second overlapping region B2 refer to overlapping regions formed by the orthographic projection of the driving circuit layer on the base substrate and the orthographic projections of different first anode regions on the base substrate. The first overlapping region B1 and the second overlapping region B2 are located in the pixel openings for different pixels. For example, the first overlapping region B1 is located in the pixel opening for the red pixel R or the pixel opening for the blue pixel B, and the second overlapping region B2 is located in the pixel opening for the green pixel G. For example, the overlapping region in the pixel opening for the red pixel R or the pixel opening for the blue pixel B that is formed by the orthographic projection of the first anode region 310A on the base substrate and the orthographic projection of the driving circuit layer on the base substrate is the first overlapping region B1; and the overlapping region in the pixel opening for the green pixel G that is formed by the orthographic projection of the first anode region 310A on the base substrate and the orthographic projection of the driving circuit layer on the base substrate is the second overlapping region B2.

As shown in FIG. 3 and FIG. 4 to FIG. 6, the driving circuit layer 200 includes a first wire 210 close to the light emitting unit layer 300. The first wire 210 includes a power signal wire 211 and a data signal wire 212. The power signal wire 211 may be used to, for example, transmit a power signal (VDD), and the data signal wire 212 may be used to, for example, transmit a data signal (Data).

Exemplarily, the pixels on the display substrate are arranged in an array in the first direction X and the second direction Y, and the power signal wire 211 and the data signal wire 212 may extend, for example, in the second direction Y.

In some embodiments of the present disclosure, the first wire 210 in the first overlapping region B1 exhibits an axisymmetric pattern. Exemplarily, the first wire 210 includes the power signal wire 211 and the data signal wire 212. As shown in FIG. 5, the power signal wire 211 in the first overlapping region B1 includes two adjacent power signal wires. The two adjacent power signal wires 211 located in the first overlapping region B1 exhibit a symmetrical pattern, and a symmetry axis of the symmetrical pattern is parallel to the second direction Y. The data signal wire 212 in the first overlapping region B1 includes two adjacent data signal wires. The two adjacent data signal wires 212 located in the first overlapping region B1 exhibit a symmetrical pattern, and a symmetry axis of the symmetrical pattern is parallel to the second direction Y.

In some exemplary embodiments of the present disclosure, the power signal wire and the data signal wire in the first overlapping region both exhibit an axisymmetric pattern, and the symmetry axis of each symmetrical pattern coincides with each other.

For example, the power signal wire 211 exhibits an axisymmetric pattern in the first overlapping region B1, and the data signal wire 212 exhibits an axisymmetric pattern in the first overlapping region B1. The symmetry axes of these two axisymmetric patterns are parallel to the second direction Y and pass through a circle center of the first overlapping region B1, that is, the symmetry axes of these two axisymmetric patterns coincide with each other, as shown by a symmetry axis XS1 in FIG. 5.

According to the embodiments of the present disclosure, by setting the first wire of the driving circuit layer in the first overlapping region B1 as an axisymmetric pattern, an anode material layer in the first anode region may not have the problem of the flatness being reduced due to a wire layout. By setting the first wire of the driving circuit layer as an axisymmetric pattern, the flatness of the anode material layer in the first anode region may be ensured, the display effect of the display substrate may be effectively improved, and the problem of ring distortion and display color shift resulted by a diffraction ring caused by large flatness may be avoided.

In the embodiments of the present disclosure, as shown in FIG. 3, the driving circuit layer 200 includes a second wire 220 away from the light emitting unit layer 300. The second wire is electrically connected to a source/drain electrode of a driving transistor in the driving circuit layer 200. The second wire and the power signal wire 211 in the second overlapping region B2 both exhibit an axisymmetric pattern. The second wire 220 is located between a film layer where the first wire 210 is located and the base substrate 100.

Exemplarily, as shown in FIG. 3, the second wire 220 is electrically connected to the source electrode or drain electrode of the driving transistor through a via hole.

In some embodiments of the present disclosure, the second wire includes a first shape compensation portion located in the second overlapping region. At least part of an outer contour of the first shape compensation portion has the same shape as at least part of an outer contour of the first anode region, and an orthographic projection of the first shape compensation portion on the base substrate overlaps at least partially with an orthographic projection of the power signal wire on the base substrate. For example, a part of the outer contour of the first shape compensation portion is the same as a part of the outer contour of the first anode region, and the first shape compensation portion is used to fill the film layer on a side of the first anode region close to the base substrate, so as to effectively improve the flatness of the first anode region.

In some embodiments, as shown in FIG. 4 and FIG. 5, the power signal wire 211 includes a second shape compensation portion 2110 located in the second overlapping region, that is, the second shape compensation portion 2110 is located in the second overlapping region B2. At least part of an outer contour of the second shape compensation portion 2110 has the same shape as at least part of the outer contour of the first anode region. As shown in FIG. 5, a part of the outer contour of the second shape compensation portion 2110 and a part of the outer contour of the first anode region are arcs overlapping with each other, so that the second shape compensation portion 2110 may compensate for the first anode region and effectively improve the flatness of the first anode region. An orthographic projection of the second shape compensation portion 2110 of the power signal wire 211 on the base substrate overlaps with the orthographic projection of the first anode region on the base substrate. For example, the power signal wire 211 and the second shape compensation portion 2110 may be formed as an integrated structure.

In other embodiments of the present disclosure, the second wire and the power signal wire in the second overlapping region both exhibit an axisymmetric pattern. For example, the second overlapping region is a circle, the symmetry axis of the second wire in the second overlapping region passes through a circle center of the second overlapping region, and the symmetry axis is parallel to the second direction Y. For another example, the symmetry axis of the power signal wire in the second overlapping region is identical with the symmetry axis of the second wire, and they are parallel to the second direction Y and pass through the circle center of the second overlapping region. For example, the second wire includes a first shape compensation portion located in the second overlapping region, at least part of the outer contour of the first shape compensation portion has the same shape as at least part of the outer contour of the first anode region, and the orthographic projection of the first shape compensation portion on the base substrate overlaps at least partially with the orthographic projection of the power signal wire on the base substrate.

In some embodiments of the present disclosure, in the second overlapping region, a total area of the power signal wire is greater than or equal to an area of the first anode region. As shown in FIG. 5, in the second overlapping region B2, the second shape compensation part 2110 included in the power signal wire 211 has a symmetry axis XS2 in the second overlapping region B2, that is, the power signal wire in the second overlapping region B2 exhibits an axisymmetric pattern.

According to the embodiments of the present disclosure, by setting the second wire and/or the power signal wire in the second overlapping region as a symmetrical pattern, the first anode region formed in the second overlapping region may have a good flatness, and the display effect of the display substrate may be improved.

In another embodiment, by providing the second wire away from the light emitting unit layer, that is, providing the second wire is located between the film layer where the first wire is located and the base substrate, the film layer on a side of the first anode region close to the base substrate may be compensated, so that an uneven thickness caused by wires provided between film layers may be reduced, and the flatness of the first anode region may be further improved.

In some embodiments of the present disclosure, in the second overlapping region, a total area of the second wire and the power signal wire is greater than or equal to the area of the first anode region. For example, in the second overlapping region, when the total area of the second wire and the power signal wire is equal to the area of the first anode region, the second wire and the power signal wire located in the second overlapping region may fully support the anode material layer of the first anode region, thereby ensuring the flatness of the anode layer of the first anode region. For another example, in the second overlapping region, when the total area of the second wire and the power signal wire is greater than the area of the first anode region, the second wire and the power signal wire have an overlapping portion, which may effectively compensate for the problem of insufficient flatness of the anode material layer in the first anode region caused by a via hole when the second wire is electrically connected to the source/drain electrode of the driving transistor through the via hole, so that the flatness of the first anode region may be improved, and the display effect of the display substrate may be improved.

In some embodiments of the present disclosure, as shown in FIG. 5, the power signal wire includes a second shape compensation portion 2110 located in the second overlapping region B2. At least part of the outer contour of the second shape compensation portion 2110 has the same shape as at least part of the outer contour of the first anode region 310A. The second shape compensation portion 2110 and the power signal wire 211 are formed as an integrated structure. The second shape compensation portion 2110 may support the anode in the first anode region, so as to improve the flatness of the first anode region.

In some embodiments of the present disclosure, the pixels of the display substrate include first sub-pixels, second sub-pixels, and third sub-pixels. The first sub-pixel and the second sub-pixel are located in different first overlapping regions B1, and the third sub-pixel is located in the second overlapping region B2. For example, the first sub-pixel is a blue pixel B, the second sub-pixel is a red pixel R, and the third sub-pixel is a green pixel G. For example, the blue pixel B is located in a first overlapping region, and the red pixel R is located in another first overlapping region. For example, the green pixel G is located in the second overlapping region B2. The first sub-pixels and the second sub-pixels are alternately arranged in the first direction and the second direction, and the first direction and the second direction form a plane parallel to an upper surface of the base substrate. For example, the blue pixels B and the red pixels R are alternately arranged in the X direction and the Y direction, for example, in a manner of BRBR . . . in both the X direction and the Y direction, and the plane formed by the X direction and the Y direction is parallel to the upper surface of the base substrate. The third sub-pixels are arranged in an array in the first direction and the second direction, and the third sub-pixels are located between adjacent first sub-pixels and between adjacent second sub-pixels. For example, the green pixels G are arranged in an array in the first direction X and the second direction Y, the green pixels G are located between two adjacent blue pixels B, and the green pixels G are located between two adjacent red pixels R. As shown in FIG. 6, four green pixels G are arranged around a red pixel, or four green pixels are arranged around a blue pixel.

In other optional embodiments, the sub-pixels of the display substrate may further include, for example, white pixels, which may be arranged in other suitable forms.

In some embodiments of the present disclosure, the pixel opening for at least one of the first sub-pixel, the second sub-pixel or the third sub-pixel has a different size from the pixel openings for other pixels.

Exemplarily, the pixel opening for the blue pixel B is larger than the pixel opening for the red pixel R and the pixel opening for the green pixel G. In other optional embodiments, the size of the pixel opening may be adjusted according to the arrangement of pixels and the display effect, which is not limited in the embodiments of the present disclosure.

In some embodiments of the present disclosure, the orthographic projection of the pixel opening on the base substrate is located within the orthographic projection of the first anode region on the base substrate. The orthographic projection of the pixel opening is located within the orthographic projection of the black matrix opening on the base substrate.

Exemplarily, as shown in FIG. 3 and FIG. 6, the orthographic projection of the pixel opening A1 on the base substrate is located within the orthographic projection A2 of the first anode region on the base substrate, that is, the area of the pixel opening is less than the area of the orthographic projection of the first anode region on the base substrate. The orthographic projection of the pixel opening A1 on the base substrate is located within the orthographic projection of the black matrix opening A3 on the base substrate, that is, the area of the pixel opening is less than the area of the black matrix opening. Through the above arrangement, it is possible to effectively prevent the problem of the first anode region being offset due to process fluctuations during the manufacturing process which may lead to a decrease in the display effect. For example, as the pixel opening has a small area, even if a position of the first anode region is offset due to process fluctuations during the manufacturing process, a case of the pixel opening failing to cover the first anode region may not occur due to a large edge region from the pixel opening to the first anode region, so that the display effect of the display substrate may be improved, and a fault tolerance rate in the manufacture process may be improved.

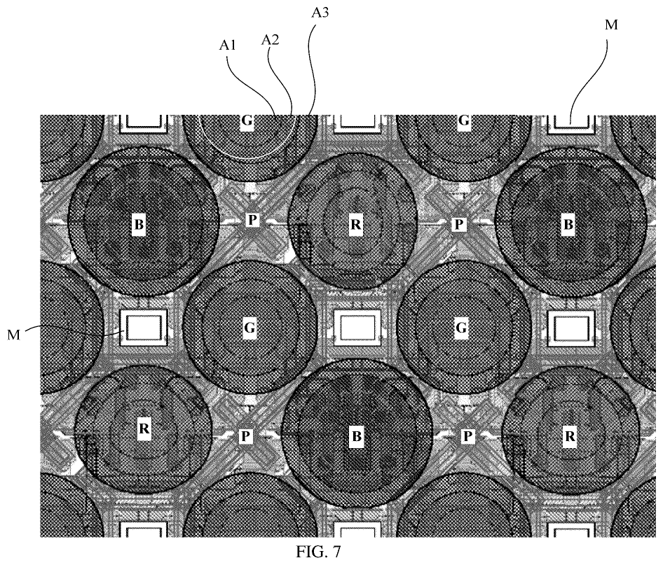

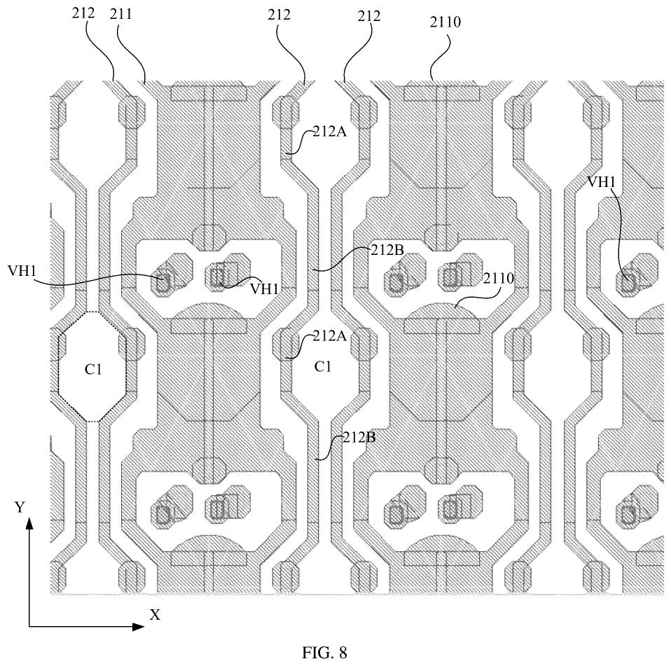

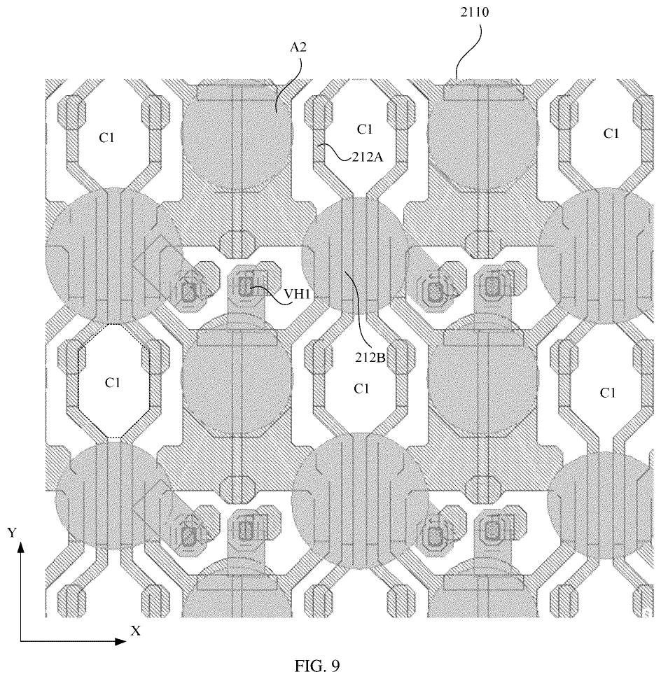

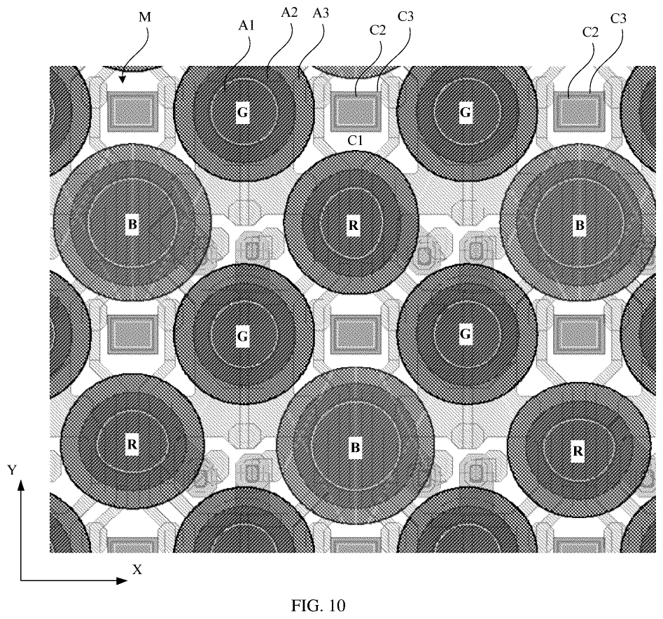

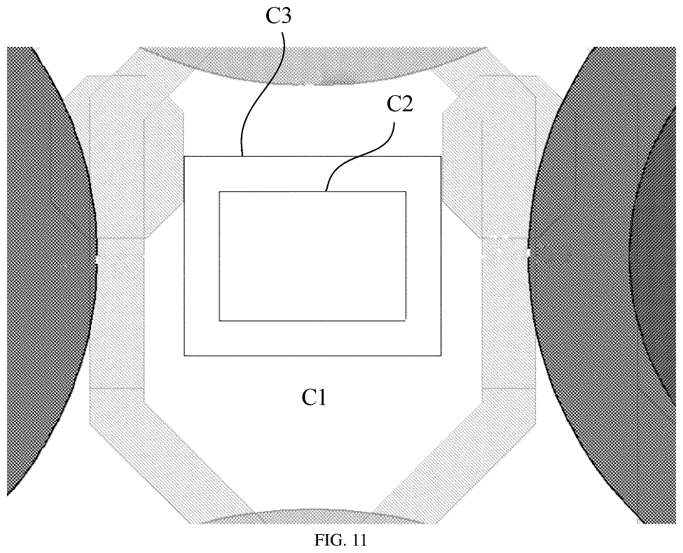

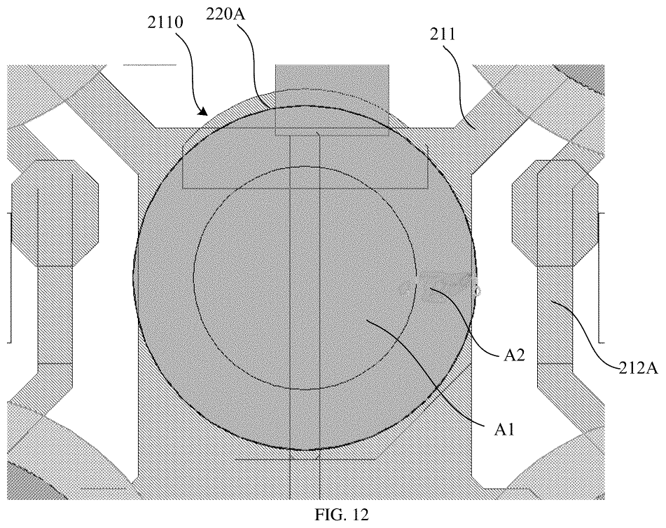

FIG. 7 shows a partial plan view of a display substrate according to some other exemplary embodiments of the present disclosure. FIG. 8 shows a partial plan view of a display substrate including a driving circuit and other film layers according to some other exemplary embodiments of the present disclosure. FIG. 9 shows a partial plan view of a display substrate including a light emitting unit layer and other film layers according to some other exemplary embodiments of the present disclosure. FIG. 10 shows a partial plan view of a display substrate including a black matrix layer and other film layers according to some other exemplary embodiments of the present disclosure. FIG. 11 shows a partial plan view of a hollow region of a display substrate according to some other exemplary embodiments of the present disclosure. FIG. 12 shows a partial plan view of a light emitting unit of a display substrate according to some other exemplary embodiments of the present disclosure.

FIG. 7 to FIG. 12 schematically show a structure of a display substrate in some other embodiments of the present disclosure. A detailed explanation of the structure of the display substrate will be described with reference to FIG. 7 and FIG. 12.

As shown in FIG. 7 and FIG. 10, the display substrate in some embodiments of the present disclosure further includes a hollow region M. The hollow region may be, for example, a region that allows light to pass through, so as to achieve a function based on a passage of light. The light in the embodiments of the present disclosure may be, for example, visible natural light or invisible light (such as ultraviolet light, infrared light, etc.). The hollow region M may be used for, for example, in-display sensing technology, and an influence of other materials on light may be reduced through the hollow region M. For example, the in-display sensing technology may be an in-display fingerprint recognition of the display substrate, and the hollow region may be, for example, a fingerprint recognition hole. For another example, the in-display sensing technology may be an in-display imaging technology of the display substrate, and the hollow region may refer to an imaging hole used to allow external light to be transmitted to an in-display sensor, such as a photosensitive element, through the hollow region.

The hollow region includes hollow regions located in different layers, such as a first hollow region located in the driving circuit layer, a second hollow region located in the pixel defining layer, and a third hollow region located in the black matrix layer.

The driving circuit layer defines a plurality of first hollow regions C1 (as shown by dashed boxes in FIG. 8 and FIG. 9), which are provided between adjacent first overlapping regions B1 and between adjacent second overlapping regions B2. For example, in the first direction X, the first hollow region C1 is located between adjacent second overlapping regions B2, and in the second direction Y, the first hollow region is located between adjacent first overlapping regions B1.

As shown in FIG. 8, the first hollow region C1 is located between adjacent data signal wires 212. The data signal wire 212 includes a bending portion 212A and a body portion 212B. The body portion 212B is located in the first overlapping region B1, and the bending portion 212A of the data signal wire 212 is bent toward a direction away from the first hollow region C1 with respect to the body portion.

Exemplarily, at least part of the body portion 212B of the data signal wire 212 is located in the first overlapping region B1 so as to ensure the flatness of the anode layer in the first anode region. The bending portion 212A of the data signal wire is bent toward a direction away from the first hollow region C1, so that the first hollow region have a large area for light to pass through, which is helpful to, for example, improve an accuracy of fingerprint recognition.

In some embodiments of the present disclosure, as shown in FIG. 8 and FIG. 9, adjacent bending portions 212A of the data signal wires 212 located on a periphery of the first hollow region C1 exhibit an axisymmetric pattern. By setting adjacent bending portions 212A of the data signal wires 212 as an axisymmetric pattern, it is possible to effectively improve the flatness of each film layer of the light emitting unit layer 300 of the display substrate, and further improve the display effect of the display substrate.

As shown in FIG. 10 and FIG. 11, the pixel defining layer defines a plurality of second hollow regions C2. An orthographic projection of the second hollow region C2 on the base substrate is located within an orthographic projection of the first hollow region C1 on the base substrate, that is, the second hollow region C2 overlaps with the first hollow region C1 in a direction perpendicular to the base substrate. The plurality of second hollow regions C2 defined by the pixel defining layer may facilitate the passage of light and achieve an effect of in-display fingerprint recognition.

As shown in FIG. 10 and FIG. 11, the black matrix layer defines a plurality of third hollow regions C3. An orthographic projection of the third hollow region C3 on the base substrate is located within the orthographic projection of the first hollow region C1 on the base substrate, that is, the third hollow region C3 overlaps with the first hollow region C1 in the direction perpendicular to the base substrate, which is helpful to achieve the effect of in-display fingerprint recognition.

Exemplarily, the second hollow region C2 may be a rectangle, with a length of 5 microns to 9 microns and a width of 4 microns to 6 microns. For example, the second hollow region has a size of 8×5.55 μm. For another example, the second hollow region has a size of 6×5 μm. The third hollow region C3 has a larger size than the second hollow region. For example, a length and a width of the third hollow region C3 are both greater than the length and the width of the second hollow region C2, that is, an opening area of the third hollow region C3 is larger than an opening area of the second hollow region C2, so as to avoid the black matrix layer blocking the second hollow region C2 due to process fluctuations, then effectively improve a light passing rate and thus improve a fingerprint recognition rate.

In some exemplary embodiments of the present disclosure, the first hollow region C1, the second hollow region C2, and the third hollow region C3 are located between a plurality of pixels. Exemplarily, the first hollow region C1, the second hollow region C2 and the third hollow region C3 included in the hollow region M of the display substrate are located between adjacent red pixels R arranged in the second direction Y and between adjacent green pixels G arranged in the first direction X, or may be located between blue pixels B and red pixels alternately arranged in the second direction Y and between adjacent green pixels G arranged in the first direction X.

As shown in FIG. 7, the display substrate further includes a touch layer which is located on a side of the color filter layer close to the base substrate. The touch layer includes a touch sensing region P provided at a diagonal intersection of four adjacent hollow regions M of the display substrate. As shown in FIG. 7, an orthographic projection of the touch sensing region P of the touch layer on the base substrate is located at a diagonal intersection of orthographic projections of four adjacent hollow regions M on the base substrate, and the touch sensing region P of the touch layer is located between four adjacent sub-pixels, for example, between two adjacent green sub-pixels G and between adjacent blue pixel B and red pixel R.

The second hollow region C2 and the third hollow region C3 have the same shape, for example, both are provided as rectangles. By providing the second hollow region C2 and the third hollow region C3 as the same shape and providing the third hollow region C3 as being larger than the second hollow region C2, it is possible to reduce a problem of the hollow region C2 being blocked due to manufacture process fluctuations, so that the fault tolerance of the display substrate in the manufacturing process may be improved, and production costs may be reduced.

In some exemplary embodiments of the present disclosure, the pixel opening, the first anode region and the black matrix opening of the display substrate have the same shape, for example, all of them are provided as circles.

In some embodiments of the present disclosure, the pixel opening may also have other shapes. For example, as shown in FIG. 6 and FIG. 10, the pixel opening for the blue pixel B and the pixel opening for the green pixel G are regular circles, and the pixel opening for the red pixel R has an irregular shape, such as a non-circle. Moreover, the wires in the overlapping regions formed by the orthographic projections of the driving circuit layers of the blue pixels B and the green pixels G and the orthographic projection of the first anode region on the base substrate exhibit an axisymmetric pattern, while the wires in the overlapping regions formed by the orthographic projections of the driving circuit layers of the red pixels R and the orthographic projection of the first anode region on the base substrate do not exhibit an axisymmetric pattern.

As shown in FIG. 12, in order to further increase the area of the hollow region of the display substrate, the power signal wire 211 in the second overlapping region B2 on a side of the first anode region A1 close to the base substrate may be arranged closer to an edge of the first anode region A1, then the bending portion 212A of the data signal wire 212 may be bent further away from the hollow region M without affecting the flatness of the first anode region, so that the area of the hollow region M may be increased, and the amount of light passing through the hollow region M may be increased. In this way, for example, the accuracy of the in-display sensing technology may be improved, for example, the accuracy of fingerprint recognition may be improved or an imaging quality of the in-display imaging may be improved. In another aspect of the present disclosure, a display device is further provided, including the display substrate as described above.

Beneficial effects that the display device in the above embodiments of the present disclosure may achieve are the same as the beneficial effects that the above-mentioned display substrate may achieve, which will not be repeated here.

The above-mentioned display device may be any device that displays a moving image (such as video) or a fixed image (such as still image) and that displays a text or an image. More specifically, it is expected that the embodiments may be implemented in or associated with various electronic devices. The various electronic devices may include (but not be limited to) a mobile phone, a wireless device, a personal data assistant (PDA), a handheld or portable computer, a GPS receiver/navigator, a camera, a MP4 video player, a video camera, a game console, a watch, a clock, a calculator, a television monitor, a flat panel display, a computer monitor, a vehicle display (such as an odometer display), a navigator, a cockpit controller and/or display, a display for camera view (such as a display of rear view camera in vehicle), an electronic photo, an electronic billboard or sign, a projector, an architectural structure, a packaging and aesthetic structure (such as a display for image of jewelry), etc.

Although some embodiments of the overall concept of the present disclosure have been illustrated and explained, those ordinary skilled in the art may understand that changes may be made to those embodiments without departing from the principle and spirit of the overall inventive concept of the present disclosure. The scope of the present disclosure is defined by the claims and their equivalents.

1. A display substrate, comprising:
a base substrate;
a driving circuit layer provided on a side of the base substrate;
a pixel defining layer located on a side of the driving circuit layer away from the base substrate, wherein the pixel defining layer defines pixel openings for a plurality of pixels, and the pixel openings are arranged in an array;
a light emitting unit layer, wherein at least part of the light emitting unit layer is provided in the pixel openings, the light emitting unit layer comprises an anode layer close to the driving circuit layer, the anode layer comprises a first anode region partially located in the pixel openings and a second anode region located outside the pixel openings, and the first anode region and the second anode region of a same pixel are electrically connected;
a black matrix layer provided on a side of the pixel defining layer away from the base substrate, wherein the black matrix layer defines a plurality of black matrix openings, and an orthographic projection of the black matrix openings on the base substrate overlaps with an orthographic projection of the pixel openings on the base substrate; and
a color filter layer provided at least partially in the black matrix openings,
wherein an orthographic projection of the driving circuit layer on the base substrate and an orthographic projection of the first anode region on the base substrate form a plurality of overlapping regions, and wires of the driving circuit layer in at least part of the overlapping regions exhibit an axisymmetric pattern.

2. The display substrate according to claim 1, wherein,
the plurality of overlapping regions comprise a plurality of first overlapping regions and a plurality of second overlapping regions, and the first overlapping regions and the second overlapping regions are located in the pixel openings for different pixels; and
the driving circuit layer comprises a first wire, wherein,
the first wire comprises a power signal wire and a data signal wire, and the power signal wire and the data signal wire in at least part of the first overlapping regions respectively exhibit an axisymmetric pattern; or
the first wire comprises a power signal wire, and the power signal wire in at least part of the first overlapping regions exhibits an axisymmetric pattern; or
the first wire comprises a data signal wire, and the data signal wire in at least part of the first overlapping regions exhibits an axisymmetric pattern.

3. The display substrate according to claim 2, wherein,
the first wire comprises the power signal wire and the data signal wire, and the power signal wire and the data signal wire in at least part of the first overlapping regions respectively exhibit an axisymmetric pattern; or
the first wire comprises the power signal wire, and the power signal wire in at least part of the first overlapping regions exhibits an axisymmetric pattern;
and wherein,
the driving circuit layer comprises a second wire, and the second wire and the power signal wire in the second overlapping region respectively exhibit an axisymmetric pattern.

4. The display substrate according to claim 3, wherein in the second overlapping region, a total area of the power signal wire is greater than or equal to an area of the first anode region, or a total area of the second wire and the power signal wire is greater than or equal to the area of the first anode region.

5. The display substrate according to claim 2, wherein the first wire comprises the power signal wire and the data signal wire, the power signal wire and the data signal wire in at least part of the first overlapping regions respectively exhibit an axisymmetric pattern, and symmetry axes of the axisymmetric patterns coincide with each other.

6. The display substrate according to claim 3, wherein the second wire comprises a first shape compensation portion located in the second overlapping region, at least part of an outer contour of the first shape compensation portion has the same shape as at least part of an outer contour of the first anode region, and an orthographic projection of the first shape compensation portion on the base substrate overlaps at least partially with an orthographic projection of the power signal wire on the base substrate.

7. The display substrate according to claim 3, wherein the power signal wire comprises a second shape compensation portion located in the second overlapping region, and at least part of an outer contour of the second shape compensation portion has the same shape as at least part of an outer contour of the first anode region.

8. The display substrate according to claim 1, wherein the anode layer is electrically connected to the wire of the driving circuit layer through an anode via hole in the second anode region.

9. The display substrate according to claim 8, wherein an orthographic projection of the anode via hole on the base substrate overlaps at most partially with an orthographic projection of the color filter layer on the base substrate.

10. The display substrate according to claim 2, wherein,
the pixels comprise first sub-pixels, second sub-pixels, and third sub-pixels;
the first sub-pixels and the second sub-pixels are respectively located in different first overlapping regions, and the third sub-pixels are located in the second overlapping regions;
the first sub-pixels and the second sub-pixels are alternately arranged in a first direction and a second direction, and the first direction and the second direction form a plane parallel to an upper surface of the base substrate; and
the third sub-pixels are arranged in an array in the first direction and the second direction, and the third sub-pixels are located between adjacent first sub-pixels and between adjacent second sub-pixels.

11. The display substrate according to claim 1, wherein the orthographic projection of the pixel opening on the base substrate is located within the orthographic projection of the first anode region on the base substrate.

12. The display substrate according to claim 1, wherein the orthographic projection of the pixel opening on the base substrate is located within the orthographic projection of the black matrix opening on the base substrate.

13. The display substrate according to claim 2, wherein the driving circuit layer defines a plurality of first hollow regions located between adjacent first overlapping regions and between adjacent second overlapping regions.

14. The display substrate according to claim 13, wherein,
the first wire comprises a power signal wire and a data signal wire, and the power signal wire and the data signal wire in at least part of the first overlapping regions respectively exhibit an axisymmetric pattern; or
the first wire comprises a data signal wire, and the data signal wire in at least part of the first overlapping regions exhibits an axisymmetric pattern:
and wherein,
the first hollow region is located between adjacent ones of the data signal wire, the data signal wire comprises a bending portion and a body portion, the body portion is located in the first overlapping region, and the bending portion of the data signal wire is bent toward a direction away from the first hollow region with respect to the body portion.

15. The display substrate according to claim 14, wherein adjacent bending portions of the data signal wire located on a periphery of the first hollow region exhibit an axisymmetric pattern.

16. The display substrate according to claim 15, wherein the pixel defining layer defines a plurality of second hollow regions, and an orthographic projection of the second hollow regions on the base substrate is located within an orthographic projection of the first hollow regions on the base substrate.

17. The display substrate according to claim 16, wherein,
the black matrix layer defines a plurality of third hollow regions, and an orthographic projection of the third hollow regions on the base substrate is located within the orthographic projection of the first hollow regions on the base substrate; and
the second hollow region has the same shape as the third hollow region.

18. The display substrate according to claim 17, wherein each of the first hollow regions, the second hollow regions, and the third hollow regions are located between a plurality of pixels.

19. The display substrate according to claim 18, further comprising a touch layer, wherein the touch layer comprises a touch sensing region provided at a diagonal intersection of four adjacent second hollow regions of the display substrate, and the touch sensing region is located between four adjacent sub-pixels.

20. A display device, comprising the display substrate of claim 1.
